(19) United States
(12) Patent Application Publication
(10) Pub. No.: US 2010/0127796 A1
(43) Pub. Date: May 27, 2010

(54) ELECTRONIC FILTER AND AN ELECTRONIC CIRCUIT FOR USE IN A SWITCHING APPLICATION

(75) Inventor: Trung Ong, Canterbury (AU)

Correspondence Address: WOODCOCK WASHBURN LLP, CIRA CENTRE, 12TH FLOOR, 2929 ARCH STREET, PHILADELPHIA, PA, 19104-2891, US

(73) Assignee: C10 Communications Pty Ltd, Regents Park New South Wales (AU)

(21) Appl. No.: 12/293,682

(22) PCT Filed: Mar. 22, 2006
(86) PCT No.: PCT/AU2006/000381

§ 371 Date: Jun. 19, 2009

(51) Int. Cl. H03H 7/12

(52) U.S. Cl. 333/174

(57) ABSTRACT

An electronic filter (100) comprising: a filter section (102, 104); an impedance correction section (106 and 108) that is electrically coupled to the filter section (102, 104); and a circuit altering section (110-116) that is arranged to alter at least one property of the impedance correction section (106, 108) to effect a shift in a resonant frequency of the impedance correction section (106, 108) from with a pass band of the filter section to within a stop band of the filter section (102, 104).

### FIELD OF THE INVENTION

The present invention relates generally to the field of electronic filters and electronic circuits for use in switching applications, and which have particular—but by no means exclusive—application to the field of asymmetric digital subscriber line (ADSL) filters for use with customer premises equipment.

### BACKGROUND OF THE INVENTION

An electronic filter is used to select and reject signals based on their frequency. An electronic filter typically comprises a combination of discrete components (such as a capacitor, inductor and/or resistor) that determine the frequency response characteristics of the filter. More recently, however, electronic filters based on digital signal processors (DSP) technology have been developed. The frequency response characteristic of DSP based filters is determined by software that is executed by the DSP.

Filters are commonly classified in to one of several categories based on their frequency response characteristics. The categories include, for example, low-pass, high-pass, band-pass and band-stop. As the category names suggest, a low-pass filter allows (selects) low frequency signals to pass while blocking (rejecting) high frequency signals. In contrast to a low-pass filter, a high-pass filter blocks low frequency signals and allows high frequency signals to pass. A band-pass filter allows signals within a certain frequency range to pass while blocking signals outside the frequency range. In contrast to a band-pass filter, a band-stop filter blocks signals within the frequency range while allowing signals outside of the frequency range to pass.

Electronic filters have a wide range of applications and, as an example of a recent application, have been used to filter asymmetric digital subscriber line services provided over copper based subscriber lines that form part of the plain old telephone system (POTS). More specifically, the filters used to filter asymmetric digital subscriber line services have been designed to be connected to customer premises equipment (CPE) such as a telephone. Furthermore, an asymmetric digital subscriber line filter is essentially a low-pass filter that allows DC and voice signals (which are in the frequency range of DC to around 4 KHz) to pass through to the customer premises equipment while blocking asymmetric digital subscriber line signals (which are in the frequency range of around 25 KHz to 1104 KHz for ADSL, and around 25 KHz to 2208 KHz for ADSL 2+) so that they do not pass through to the customer premises equipment.

While today's asymmetric digital subscriber line filters generally perform well as low-pass filters they do have some drawbacks. A notable drawback is that many asymmetric digital subscriber line filters are not suitable for being installed in a distributed arrangement at a customer premises. In a distributed arrangement a separate filter is plugged into each telephone socket located on the customer premises, which essentially results in multiple filters being connected, in parallel with each other, to a single subscriber line. Unfortunately, when existing asymmetric digital subscriber line filters are connected in parallel with each other the filtering performance of each individual filter can be degraded. More specifically, the degradation in the filtering performance can be attributed to the parallel loading effect caused by the impedance of the low-pass filtering circuits (which are in parallel with each other).

Many of today's electronic filters comprise semiconductor based switching circuits (that are typically based on transistors) to selectively switch electronic components in or out of the filtering circuitry. The semiconductor devices may, for example, be employed in an asymmetric digital subscriber line filter to switch electronic components in or out in response to the presents or absence of a subscriber line loop current. On examining existing semiconductor based switching circuits used in many of today's electronic filters, the inventor surprising discovered that the existing semiconductor based switching circuits can introduce significant noise in to the pass-band of the filter. Upon further investigation the inventor discovered that the noise is often the result of the non-linear characteristics of the pn-structure that exists between the collector and base of a transistor used in the semiconductor based switching circuits in the absence of a subscriber line loop current (such as filter connecting to CPE in on-hook state and in parallel to other filters on the same line).

In the case of asymmetric digital subscriber line filters, the inventor discovered that traditional semiconductor based switching circuits generated little unwanted noise when used in conjunction with early asymmetric digital subscriber line technology (signals). However, the inventor also discovered that when used with later asymmetric digital subscriber line technology (signals) such as ADSL2+ the traditional semiconductor based switching circuits generated considerable unwanted noise in the pass-band of the filter in the absence of a subscriber line loop current (such as filter connecting to CPE in on-hook state and in parallel to other filters on the same line), which the inventor discovered was the result of the higher signal power used in ADSL2+.

### SUMMARY OF THE INVENTION

According to a first aspect of the present invention there is provided an electronic filter comprising:

a filter section;

an impedance correction section that is electrically coupled to the filter section; and

a circuit altering section that is arranged to alter at least one property of the impedance correction section to effect a shift in a resonant frequency of the impedance correction section from within a pass band of the filter section to within a stop band of the filter section.

An advantage of a filter according to an embodiment of the first aspect of the present invention is that by shifting the resonant frequency of the impedance correction section it is possible to improve the stop band attenuation of the filter when, for example, a telephone (or any other customer premises equipment) connected to the filter is in an on-hook state. The effect of improving the stop band attenuation is that the filter can still provide reasonable amounts of attenuation against signals outside of the voice band, which is particularly useful for facilitating the exchange of on-hook communication signals such as coded DTMF signals, metering pulse signals or caller ID signals.

Preferably, the circuit altering section is arranged to alter at least one property of the filter section to effect an increase in a stop band impedance of the filter section.

An advantage of increasing the stop-band impendence is that it minimizes the parallel loading effect on other filters that may be connected in parallel to the filter.

Preferably, the property of the filter section comprises a capacitance, and wherein the circuit altering section is arranged to effect the increase in the stop band impendence by reducing the capacitance to a value that is greater than zero Farad.

An advantage of reducing the capacitance to greater than zero Farad is that instead of completely removing the capacitance (reduced to zero) it ensures the filter section retains some stop-band attenuation when, for example, the telephone connected to the filter is in an on-hook status.

Preferably, the circuit altering section is arranged to alter the property of the impedance correction section and to alter the property of the filter section based on a subscriber line loop current.

An advantage of altering the property based on the subscriber line loop current is that it provides an easy method for switching based on whether a telephone is in an on-hook state or an off-hook state.

Preferably, the property of the impedance correction section comprises a damping resistance and a capacitance, and wherein the circuit altering section is arranged to effect the shift in the resonant frequency by decreasing the capacitance, and wherein the circuit altering section is further arranged to increase the damping resistance.

Preferably, the filter section comprises a plurality of cascaded low pass filters arranged such that the cut-off frequency associated with the pass band and the stop band is around 12 KHz.

Preferably, the impedance correction section comprises a parallel resonant circuit that is electrically coupled to a first of the cascaded low pass filters and a second of the cascaded low pass filters.

Preferably, the circuit altering section comprises at least one semiconductor device arranged to alter the property of the impedance correction section and to alter the property of the filter section.

According to a second aspect of the present invention there is provided an electronic filter comprising:

a filter section; and

a circuit altering section that is arranged to alter at least one property of the filter section to effect an increase in a stop band impedance of the filter section.

Preferably, the filter further comprises an impedance correction section, and wherein the circuit altering section is arranged to alter at least one property of the impedance correction section to effect a shift in a resonant frequency of the impedance correction section from within a pass band of the filter section to within a stop band of the filter section.

Preferably, the property of the filter section comprises a capacitance, and wherein the circuit altering section is arranged to effect the increase in the stop band impendence by reducing the capacitance to a value that is greater than zero farad.

Preferably, the circuit altering section is arranged to alter the property of the impedance correction section and to alter the property of the filter section based on a subscriber line loop current.

Preferably, the property of the impedance correction section comprises a damping resistance and a capacitance, and wherein the circuit altering section is arranged to effect the shift in the resonant frequency by decreasing the capacitance, and wherein the circuit altering section is arranged to increase the damping resistance.

Preferably, the filter section comprises a plurality of cascaded low pass filters arranged such that the cut-off frequency associated with the pass band and the stop band is around 12 KHz.

Preferably, the impedance correction section comprises a parallel resonant circuit that is electrically coupled to a first of the cascaded low pass filters and a second of the cascaded low pass filters.

Preferably, the circuit altering section comprises at least one semiconductor device arranged to alter the property of the impedance correction section and to alter the property of the filter section.

According to a third aspect of the present invention there is provided an electronic circuit for use in a switching application, the electronic circuit comprising:

a transistor switch arrangement comprising a base semiconductor region of a first type; and

a semiconductor device having a pn-structure comprising a semiconductor region of the first type that is electrically coupled to the base semiconductor region.

An advantage of an electronic circuit embodying the third aspect of the present invention is that it has the potential to ameliorate pass-band noise that may be generated by existing semiconductor based switching circuits.

Preferably, the semiconductor device comprises a transistor actuator arrangement arranged to switch the transistor switch arrangement between an on-state and an off-state.

Preferably, the transistor switch arrangement and the transistor actuator arrangement define a complementary transistor pair in which: a collector of the transistor actuator arrangement is electrically coupled to a base of the transistor switch arrangement; and a base of the transistor actuator arrangement is electrically coupled to an emitter of the transistor switch arrangement, which is also electrically coupled to an emitter of the transistor actuator arrangement.

### A BRIEF DESCRIPTION OF THE FIGURES

Notwithstanding any other embodiments that may fall within the scope of the present invention, an embodiment of the present invention will now be described, by way of example only, with reference to the accompanying figures, in which:

FIG. 1(a) is a schematic representation of an embodiment of a filter according to the present invention;

FIGS. 1(b) to 1(e) are schematic representations of alternative embodiments of a section of the filter depicted in FIG. 1(a); and

FIGS. 2(a) to 2(e) are schematic representations of transistor based switching circuits.

### AN EMBODIMENT OF THE INVENTION

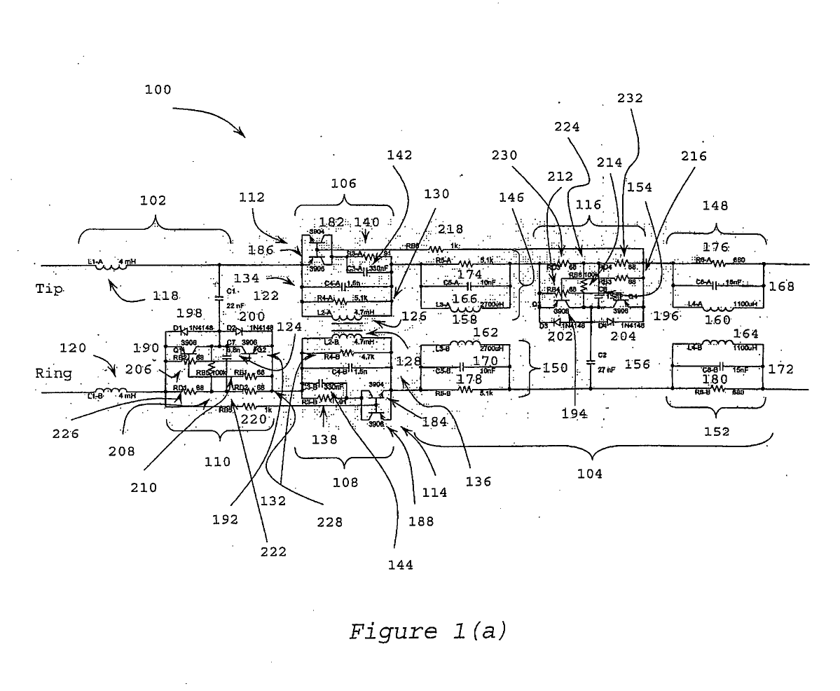

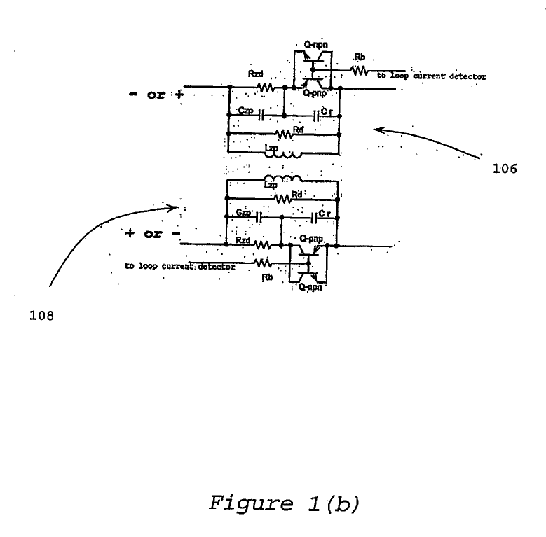

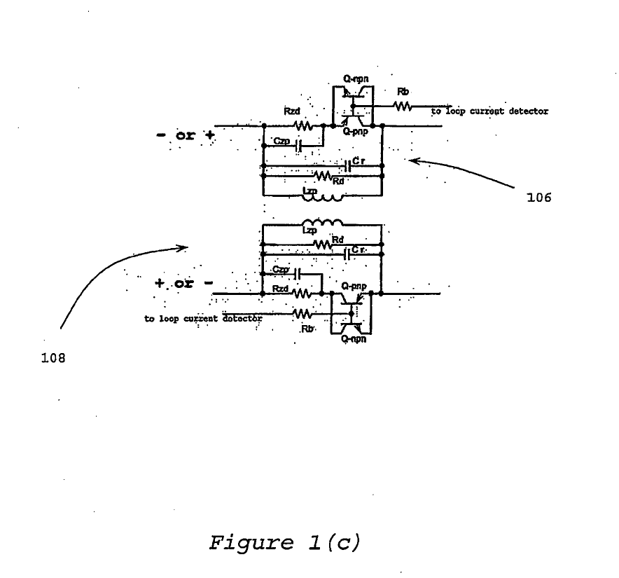

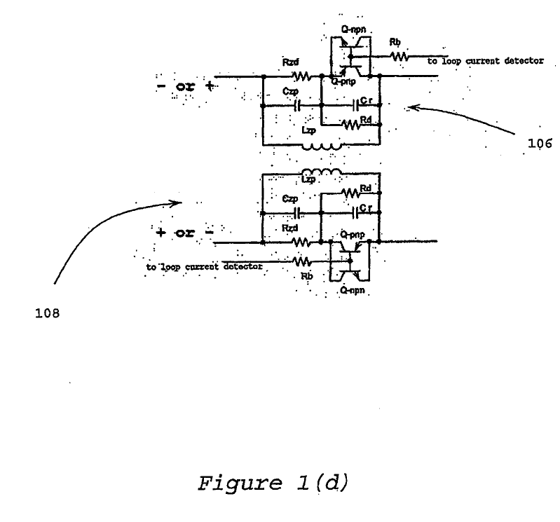

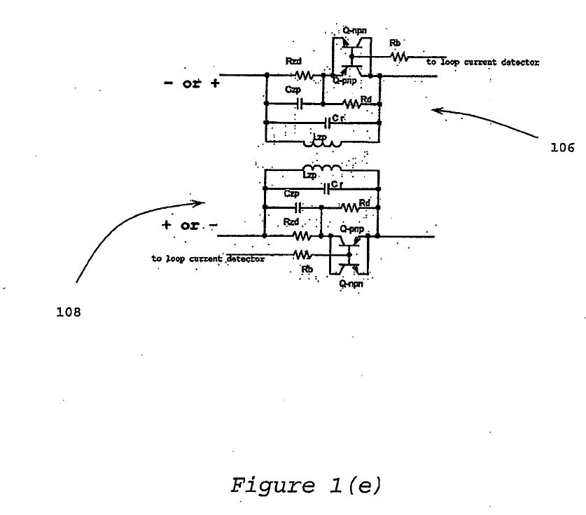

FIG. 1(a) depicts a schematic diagram of an electronic filter 100, in accordance with an embodiment of the present invention, which is particularly suited to use as an asymmetric digital subscriber line filter for customer premises equipment (for instance, a home telephone). As such, persons skilled in the art will readily appreciate that the filter 100 is intended to be electrically coupled to a subscriber line of a plain old telephone system and electrically coupled to the customer premises equipment.

Persons skilled in the art will also appreciate that the filter 100 basically acts as a low-pass filter that allows DC and signals in a voice band (which means approximately DC to around 4 KHz) on the subscriber line to pass through to the customer premises equipment, while blocking (attenuating) signals in an asymmetric digital subscriber line band (which extends approximately between 25 KHz to over 2208 KHz) from passing through to the customer premises equipment.

As can be seen in FIG. 1(a) the filter 100 comprises an inverted-L low-pass filter 102 and a T-type low-pass filter 104, which together form a filter section. In addition to the filters 102 and 104, the filter 100 comprises a pair of parallel resonant circuits 106 and 108, which together form an impedance correction section, that are electrically interposed between the inverted-L filter 102 and the T-type filter 104. The filter 100 also comprises several transistor based circuits 110 to 116, which together form a circuit altering section. One of the circuits 110 is electrically connected to the inverted-L low pass filter 102, while two of the circuits 112 and 114 are electrically connected to the parallel resonant circuits 106 and 108. Furthermore, one of the circuits 116 is electrically connected to the T-type low-pass filter 104.

The inverted-L low-pass filter 102 comprises two inductors 118 and 120, each of which has an inductance of about 4 mH. One of the inductors 118 is intended to be electrically coupled in series to the “tip” line of the subscriber line, while the other inductor 120 is intended to be electrically coupled in series to the “ring” line of the subscriber line. It is envisaged that the tip and ring lines maybe reversed. The low-pass filter 102 includes the two inductors 118 and 120 to maintain the balanced aspect of the subscriber line. In addition to the inductors 118 and 120, the inverted-L low-pass filter 102 comprises two capacitors 122 and 124 that are electrically connected in series with each other. The capacitors 122 and 124 are also electrically connected across the inductors 118 and 120 to form an inverted-L low-pass filter arrangement. One of the capacitors 122 has a capacitance of 22 nF, while the other capacitor 124 has a capacitance of 6.8 nF. The capacitors 122 and 124 are also known as “shunt capacitors”.

As persons skilled in the art will readily appreciate, the values of the inductors 118 and 120 and the values of the capacitor 122 result in the low-pass filter 102 having a pass-band in the frequency range of approximately DC to 12 KHz and a stop-band in the frequency range of about 25 KHz to over 20 MHz. The pass-band of the low-pass filter 102 is such that DC and voice (audio) information on the subscriber line will pass through the low-pass filter 102, while the stop-band band will prevent (attenuate) asymmetric digital subscriber line signals on the subscriber line from passing through the low-pass filter 102.

As outlined in previous paragraphs of this specification, the filter 100 also comprises a pair of parallel resonant circuits 106 and 108. One of the resonant circuits 106 is connected in series with one of the inductors 118 of the inverted-L low-pass filter 102, while the other resonant circuit 108 is connected in series with the other inductor 120 of the inverted-L low-pass filter 102. The filter 100 includes the two resonant circuits 106 and 108 to maintain the balanced characteristic of the subscriber line. Each resonant circuit 106 and 108 includes an inductor 126 and 128, a damper resistor 130 and 132 and a capacitor 134 and 136, all of which are electrically connected in parallel with each other. Each of the inductors 126 and 128 has a value of about 4.7 mH (two windings of a 1:1 transformer), while the resistors 130 and 132 each have a value of 5.1 kOhm. Each capacitor 134 and 136 has a value of 1.5 nF. Each resonant circuit 106 and 108 also comprises another resistor 138 and 140 and another capacitor 142 and 144. The additional resistor 138 and 140 and capacitor 142 and 144 are connected in parallel with each other. Furthermore, the additional resistor 138 and 140 and capacitor 142 and 144 are electrically connected to the inductor 126 and 128, the resistor 130 and 132, and the capacitor 134 and 136. The additional resistor 138 and 140 and capacitor 142 and 144 is also electrically connected to the transistor based circuit 112 and 114.

As persons skilled in the art will readily appreciate, the values of the inductors 126 and 128 and the capacitors 134, 136, 142 and 144 determine the resonant frequency of the resonant circuits 106 and 108, while the damping resistors 130, 132, 138 and 140 determine the damping factors (Q) of the resonant circuits 106 and 108. The primary purpose of the resonant circuits 106 and 108 is to ensure the impedance of the filter 100 is approximately equal to the impedance of the subscriber line, which in turn sets the return loss of the filter 100 as high as possible. As outlined in more detail in subsequent paragraphs of this specification, the resonant circuits 106 and 108 are also used (selectively) to increase the attenuation of signals (ADSL) in the stop-band of approximately 30 KHz to 1104 KHz.

As described in previous paragraphs of this specification, the filter 100 also comprises a T-type filter 104. The T-type filter 104 comprises four parallel resonant circuits 146 to 152 and two capacitors 154 and 156. Two of the resonant circuits 146 and 148 are electrically connected in series with each other, and are also electrically connected in series with one of the resonant circuits 106 that forms the impedance correction section. The other two resonant circuits 150 and 152 of the T-type filter 104 are also electrically connected in series with each other, and are also electrically connected in series with the other resonant circuit 108 that forms the impedance correction section. Having the resonant circuits 146 to 152 organised in symmetric pairs that are electrically connected to the resonant circuits 106 and 108 preserves the balanced characteristic of the subscriber line. The two capacitors 154 and 156 are electrically connected in series with each other. Furthermore, the two capacitors are electrically disposed between a first pair of the resonant circuits 146 and 150 and a second pair of the resonant circuits 148 and 152, to thereby form a T-type low pass filtering section.

Each parallel resonant circuit 146 to 152 comprises an inductor 158 to 164, a capacitor 166 to 172, and a damping resistor 174 to 180, all of which are electrically connected in parallel with each other. The inductor 158 and 162 in two of the resonant circuits 146 and 150 has an inductance of about 2700 μH, while the capacitor 166 and 170 of the resonant circuits 146 and 150 has a capacitance of about 10 nF. Furthermore, the resistor 174 and 178 in each of the two resonant circuits 146 and 150 has a resistance of about 5.1 kOhm. The inductor 160 and 164 in the other two resonant circuits 148 and 152 has an inductance of bout 1100 μH, while the capacitor 168 and 172 in the other two resonant circuits 148 and 152 has a capacitance of about 15 nF. The resistors 176 and 180 in the other two resonant circuits 148 and 152 has a resistance of about 680 Ohms.

Persons skilled in the art will readily appreciate that the values of the inductors 158 to 164, the capacitors 166 to 172, and the resistors 174 to 180 results in the T-type filter 104 having a cut-off frequency at about 13 KHz, and further provides sharp and deep attenuation at around 30 KHz. The pass-band of the T-type filter 104 is such that voice (audio) information including DC in the pass band (that is, DC to around 13 KHz) will pass through the filter 104, while the stop-band band will prevent (severely attenuate) asymmetric digital subscriber line signals on the subscriber line from passing through the filter 104.

As outlined in a previous paragraph of this specification, the filter 100 comprises several transistor based circuits 110 to 116. As described in more detail in subsequent text of this specification, the main function provided by two of the transistor based circuits 112 and 114 is to bring about a change in at least one properties of the impedance correction circuits 106 and 108 in order to effect a change in the circuits' resonant frequencies. The main function provided by the other two transistor circuits 110 and 116 is to bring about a change in at least one property of the inverted-L filter 102 and the T-type filter 104 in order to effect an increase in a stop-band impedance of the filters 102 and 104.

The transistor circuits 112 and 114 used to bring about a change in the property of the impedance correction circuits 106 and 108 each comprises an NPN transistor 182 and 184 and a PNP transistor 186 and 188. The other transistor circuits 110 and 116 each comprise two PNP transistors 190 to 196. Furthermore, the transistor based circuits 110 and 116 each comprises two diodes 198 to 204 arranged to form a full bridge (or in an alternative embodiment two NPN transistors with diodes 198 to 204 reversed) as well three resistors 206 to 216. The NPN transistors 182 and 184 are in the form of 3904 series transistors, while the PNP transistors 186 to 196 are in the form of 3906 series transistors. The diodes 198 to 204 are of the 1N4148 type. Two of the resistors 206, 210, 212 and 216 in each transistor circuit 110 and 116 have a resistance of 68 Ohms, while the other resistor has a resistance of 100 kOhms.

With regard to the transistor circuits 110 and 116 that are used to bring about a change in a property of the inverted-L filter 102 and the T-type filter 104, the two transistors 190 to 196 in each circuit 110 and 116 have their collectors electrically coupled together and also electrically coupled between the two capacitors (shunt capacitors) 122, 124, 154 and 156 of the filters 102 and 104 such that the collectors are electrically disposed between the two capacitors 122, 124, 154 and 156. Furthermore, the collectors of the transistors 190 to 196 are electrically coupled to the common anode of the diodes 198 and 200. When there is no loop current through the filter 100 (that is, the customer premises equipment is in an on-hook state), the transistor circuits 110 and 116 are in a turned-off state, the common anodes of the diodes 198 and 200 and the collector of transistors 190 and 196 exhibit a high impedance, the shunt capacitor 122 and 156 is isolated from being electrically connected to the invented-L low pass filter 102 and the T-type filter 104, except bleeding through small capacitance 124 and 154 in series with 122 and 156, and forming weak inverted-L filter 102, and weak T-type filter 104, which is the result of the effective shunt capacitor being reduced. However, any information exchange between Line port and POTS port of the filter 100 during this ON HOOK state of the customer premises equipment is maintained via the by pass resistors 226 and 228 and 230 and 232 which are electrically across the transistor-diode bridge circuits 110 and 116. When there is loop current through (CPE Off Hook) filter 100, the transistor-diode bridge 110 and 116 is turn on, the common anode and collector joining point of the transistor-diode bridge 110 and 116 exhibit low impedance, and the shunt capacitor 122 is connected to inductor 120 of inverted-L filter 102, and the impedance correction resonant circuit 108, and becomes a stronger inverted-L filter 102, shunt capacitor 156 is connected to two adjacent resonant circuits 146 and 148 and becomes a stronger T-type filter 104.

The emitters of the transistors 190 and 192 in one of the transistor circuits 110 are electrically disposed (connected) between an inductor 120 of the inverted-L low-pass filter 102 and the parallel resonant circuit 108 to which the inductor 120 is electrically connected in series with. The emitters of the transistors 194 and 196 in the other transistor circuit 116 are electrically disposed (connected) between two of the series connected resonant circuits 146 and 148 in the T-type filter 104. The base of each transistor 190 to 196 is electrically connected, via one of the resistors 206, 210, 212 and 216 to the base of the other transistor 190 to 196 in the associated transistor based circuit 110 and 116. Each diode 198 to 204 in the transistor based circuits 110 and 116 is electrically connected across the emitter and collect of a unique transistor 190 to 196 in the transistor circuits 110 and 116.

With regard to the transistor circuits 112 and 114 used to bring about a change in the property of the impedance correction circuits 106 and 108, the two transistors 182 to 188 in each of these circuits 112 and 114 have there bases electrically connected together. Furthermore, the bases of the transistors 182 and 186 in one of the circuits 112 are electrically disposed (connected), via a 1 kOhm resistor 218, between two of the series connected resonant circuits 146 and 148 in the T-type filter 104. In addition to being electrically connected together, the bases of the transistors 184 and 186 in the other transistor circuit 114 are electrically disposed (connected), via a 1 kOhm resistor 220, between an inductor 120 of the inverted-L filter 102 and the corresponding series connected parallel resonant circuit 108.

The emitters of the transistors 182 and 186 in one of the transistor circuits 112 are electrically connected together and are also electrically connected to one of the inductors 118 in the inverted-L filter 102. The collectors of the same transistors 182 and 186 are also electrically connected together and are electrically connected to the additional resistor 140 and the capacitor 142 in one of the resonant circuits 106, which forms the impedance correction section. The emitters of the transistors 184 and 188 in the other transistor circuit 114 are electrically connected together and also electrically connected to one of the resonant circuits 150 in the T-type filter 104. The collectors of the same transistors 184 and 188 are electrically connected together and also electrically connected to the additional resistor 138 and the additional capacitor 144 in one of the parallel resonant circuits 108, which forms the impedance correction section.

The primary function provided by two of the transistor based circuits 112 and 114 is to selectively switch the additional resistors 138 and 140 and capacitors 142 and 144 in or out of in the parallel resonant circuits 106 and 108, to thereby alter the properties (being the resistance and capacitance) of the circuits 106 and 108 in order to shift the resonant frequencies of the circuits 106 and 108 between the pass-band and stop-band of the inverted-L filter 102 and the T-type filter 104. The primary function provided by the other two transistor circuits 110 and 116 is to selectively ‘switch’ capacitors 124 and 154 in or out of the inverted-L filter 102 and T-type filter 104. The purpose of switching the capacitors 124 and 154 in or out of the filters 102 and 104 is to bring about a change in a property (capacitance) of the filters 102 and 104 to either increase or decrease the stop-band impedance of the filters 102 and 104.

In relation to the operation of the transistor circuits 110 and 116, each comprises two diodes 198 to 204, and two transistors 190 to 196 and their base resistors 206 to 216, which form a bridge such that when there is loop current through filter 100 (CPE Off Hook), a transistor 190 to 196 and a diode 198 to 204 in series in the bridge are forward biased, and the bridge center joint (collectors and anodes joining together) is conducted (switched on) through the forward biased transistor and diode 198 to 204. When there is no loop current through filter 100 (CPE On Hook), none of the transistors 190 to 196 nor diodes 198 to 204 is forward biased, the bridge center joint (where collectors and anodes are joining together) is high impedance (switch off), however information exchange through filter 100 during the CPE ON HOOK state is maintained via the by-pass resistors 226 to 232, which are electrically across the circuits 110 and 116.

In relation to the transistor circuit 110 and 116, the transistors 190 to 196 the PNP transistors are in the form of 3906 series transistors; however, NPN type of transistor in the form of 3904 series are also possible (in an alternative embodiment of the present invention) to the same effect when the polarity of the diodes 198 to 204 is reversed. The NPN transistors 182 and 184 are in the form of 3904 series transistors, while the PNP transistors 186 to 196 are in form of 3906 series transistors. The diodes 198 to 204 are of the IN4148 type.

With regard to the transistor circuits 110 and 116 that are used to bring about a change in a property of the inverted-L filter 102 and the T-type filter 104, the transistor circuit 110 and 116 have their collectors of transistor 190 to 196 and anodes of diodes 198 to 204 electrically coupled together (bridge center joint), and also electrically coupled between the two capacitors (shunt capacitors) 122, 124, 154, and 156 of the filters 102 and 104. The emitters of the transistors 190 and 192, and the cathodes of diodes 198 and 200 in one of the transistor circuits 110 are electrically disposed (connected) between an inductor 120 of the invert-L low pass filter 102 and the parallel resonant circuit 108 to which the inductor 120 is electrically connected in series. The emitters of the transistors 194 and 196, and the cathodes of diodes 202 and 204 in the other transistor circuit 116, are electrically disposed (connected) between two of the series connected resonant circuit 146 and 148 in the T-type filter 104.

The primary function provided by two of the transistor based circuits 110 and 116 is to selectively alter the shunt capacitance of the inverted-L low pass filter 102, and alter the shunt capacitance of the T-type low pass filter 104. When there is no loop current through (CPE ON Hook) filter 100, the transistor-diode bridge 110 and 116 is turned off, the bridge center (where collectors of transistor 190 to 196 and anodes of diodes 198 to 204 are electrically coupled together) of circuit 110 and 116 exhibit high impedance, the shunt capacitor 122 and 156 is isolated from connecting to the inverted-L low pass filter 102 and T-type filter 104, except bleeding through a small capacitor 124 and 154 in series with 122 and 156 to form a weak inverted-L filter 102 and a weak T-type filter 104, which is the result of the effective shunt capacitor being reduced. However, any information exchange between Line port and POTS port during the ON HOOK state of CPE is maintained via the by-pass resistors 226 to 230 and 232, which are across the transistor-diode bridge 110 and 116. When there is loop current through (CPE Off Hook) filter 100, the transistor-diode bridge 110 and 116 is turned on, the bridge center (where collectors of transistor 190 to 196 and anodes of diodes 198 to 204 are electrically coupled together) of circuit 110 and 116 exhibit low impedance, and the shunt capacitor 122 is disposed (connected) between an inductor 129 of the inverted-L filter 102, and the impedance correction resonant circuit 108 to become a stronger inverted-L filter 102. Shunt capacitor 156 is disposed (connected) between two resonant circuits 146 and 148 and become a stronger T-type filter 104.

With regard to the transistor circuit 112 and 114 used to bring about a change in the property of the impedance correction resonant circuit 106 and 108. The two transistors 182 to 188 in each of these circuits 112 and 114 have their emitters electrically connected to one end of the inductors 126 and 128 of the resonant circuit 106 and 108, and their collectors electrically connected to the parallel resonant capacitors 142 and 144, and damper resistors 138 and 140 which are in turn connected to the other end of the inductors 126 and 128. The bases of the transistor circuits 112 and 114 are connected via a base resistor 218 and 220 to the far end of transistor circuit 110 and 116 as a source of detecting on off hook status of the CPE connected to the filter 100. The transistor circuit 112 and 114 comprise a complementary pair of transistor NPN and PNP in form of 3906 and 3904 series transistor. However, only one of the transistors acts as a transistor based switch depending on the DC polarity on the tip and ring terminal of the subscriber line.

The primary function provided by two of the transistor based circuits 112 and 114 is to selectively ‘switch’ the resonant capacitors 142 and 144 and the damper resistors 138 and 140 in or out of the parallel resonant circuit 106 and 108, to thereby alter the properties (being the resonant capacitor and damping resistor) of the resonant circuits 106 and 108 in order to shift the resonant frequencies of the circuit 106 and 108 depending on the CPE connected to the filter 100 being “off hook” or “on hook”. When the CPE connected to filter 100 is “Off hook”, the transistor based circuit 112 and 114 is conducting (switched ON), resulting in the total resonant capacitor being the sum of capacitors 134 and 140, and sum of capacitors 136 and 144, the resonant frequency of circuit 112 and 114 is within the voice band, and the damping resistance being parallel resistors 130 and 140 in circuit 112, and the damping resistor being parallel resistors 132 and 138 in circuit 114. Circuit 112 and 114 serve to compensate for the impedance of filter 100 to the line (when the CPE connected to filter 100 is OFF Hook). When the CPE connected to filter 100 is “On hook”, the transistor based circuit 112 and 114 is off (non conducted), the capacitors 142 and 144, and resistor 138 and 140 are removed from circuit 112 and 114, with much less capacitance with only capacitor 134 and 136 in circuit 106 and 108 the resonant frequency of circuit 106 and 108 is shifted to a much higher frequency in the stop band at around 30 kHz. The circuits 106 and 108 serve as additional parallel resonant tank circuits to the T-type low pass filter 104, which provide filter 100 with more attenuation to ADSL signals even when CPE is in an ON-HOOK state without scarifying the parallel loading effect to any other filters in parallel.

The subscriber line loop current will flow through the filter 100 when the filter 100 is electrically connected to a subscriber line and customer premises equipment (such as a home telephone). Furthermore, the subscriber line loop current will flow when the customer premises equipment is in an off-hook state. When the customer premises equipment is in an on-hook state the subscriber line loop current will not flow through the filter 100.

As persons skilled in the art will readily appreciate, the present invention is not restricted to the particular arrangement of electronic components depicted in FIG. 1(a). For instance, it is envisaged that instead of using the resonant circuits 106 and 108 depicted in FIG. 1(a), the filter 100 could employ the alternative resonant circuits 106 and 108 depicted in FIGS. 1(b) to 1(e).

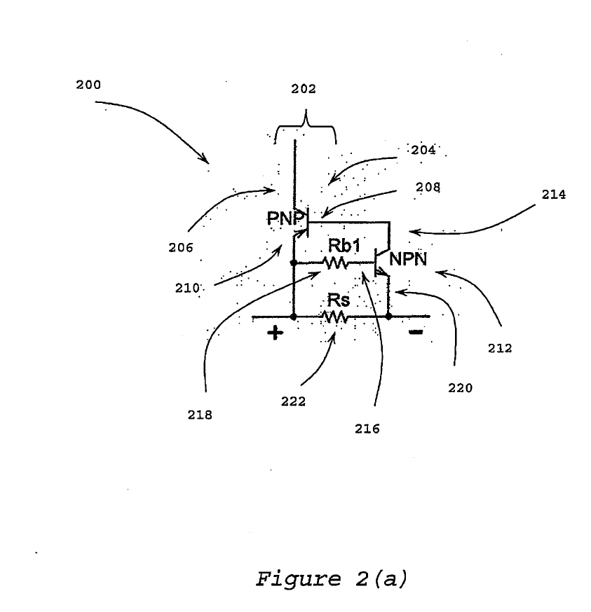

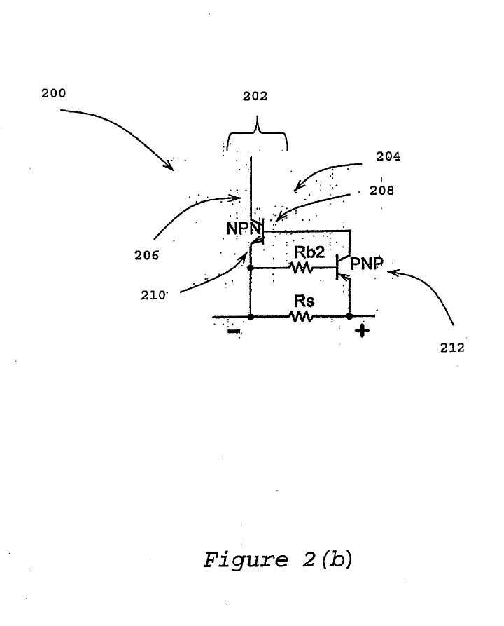

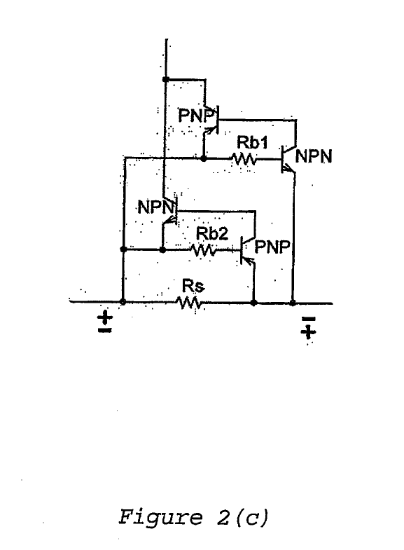

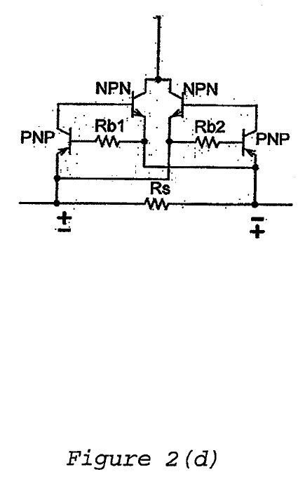

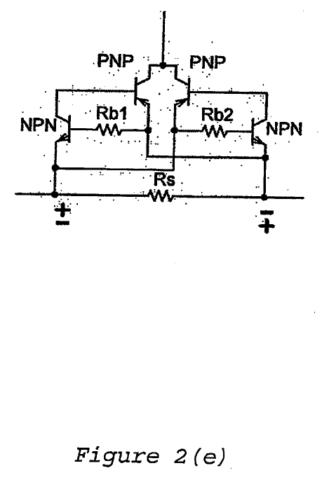

As indicated in the “Background of the Invention” section of this specification, the inventor has surprisingly discovered that semiconductor based switching circuits, such as the transistor based circuits 110 to 116 depicted in FIG. 1(a), can be susceptible to generating unwanted noise in the pass-band of the filter sections 102 and 104 in the absence of a subscriber line loop current (such as filter connecting to CPE in on-hook state and in parallel to other filters on the same line). While the transistor based circuits 110 to 116 tend not to generate unwanted noise when used in conjunction with early asymmetric digital subscriber line technology (signals), the circuits 110 to 116 may have a tendency to generate unwanted noise in the filters' 102 and 104 pass-band when used with later asymmetric digital subscriber line technology (signals) such as ADSL2+. To ameliorate the unwanted noise when used with later asymmetric digital subscriber line technology (signals), the transistor based circuits 110 to 116 can be replaced with switching arrangements based on the circuits 200 depicted in FIGS. 2(a) and 2(b).

With reference to FIGS. 2(a) and 2(b), each circuit 200 comprises a transistor switch arrangement 202 comprising a transistor 204 that has a collector 206, a base 208 and an emitter 210. The transistor 204 depicted in FIG. 2(a) is a PNP transistor and consequently the collector 206 and the emitter 210 are each associated with a separate P-type semiconductor region. On the other hand, the base 208 is associated with an N-type semiconductor region. In contrast to FIG. 2(a), the transistor 204 depicted in FIG. 2(b) is an NPN transistor and as such the collector 206 and the emitter 210 are each associated with a separate N-type semiconductor region. The base 208, however, is associated with a P-type semiconductor region.

In addition to the transistor switch arrangement 202, each circuit 200 comprises a semiconductor device 212 that has a pn-structure that comprises a semiconductor region that is of a type that is the same as the region associated with the base 208 of the transistor 204. As a result, the pn-structure has an N-type region in the case of the transistor 204 depicted in FIG. 2(a) and a P-type region in the case of the transistor 204 depicted in FIG. 2(b). More specifically, the semiconductor device 212 is in the form of an NPN transistor in the circuit 200 of FIG. 2(a), or a PNP transistor in the circuit 200 of FIG. 2(b). Consequently, the transistor switch arrangement 202 and the semiconductor device 212 forms a complementary transistor pair; that is, two different types of transistors consisting of an NPN transistor and a PNP transistor.

The base 208 of the transistor switch arrangement 202 electrically coupled to the collector 214 of the semiconductor device 212, while the base 216 of the semiconductor device 212 is electrically coupled to the emitter 210 of the transistor switch arrangement 202 via a resistor 218. The emitter 220 the semiconductor device 212 is electrically coupled to the emitter 210 of the transistor switch arrangement 202 via another resistor 222.

The semiconductor device 212 is arranged to switch the transistor switch arrangement 202 between an on-state and an off-state by setting the electrical potential of the base 208 of the transistor 204 relative to the emitter 210 of the transistor 204. In the on-state, current or signals can flow through the transistor 204 via its collector 206 and emitter 210. In the off-state, current or signals cannot flow through the transistor 204 via its collector 206 and emitter 210.

An advantage of the circuits 200 depicted in FIGS. 2(a) and 2(b) is that the non-linear characteristics of the pn-structure between the collector 206 and the base 208 of the transistor 204 are ameliorated by the pn-structure between the collector 214 and the base 216 of the semiconductor device 212. By ameliorating the non-linear characteristics of the pn-structure, the switching circuits 200 are less likely to generate unwanted noise in the pass-band of the filters 102 and 104 when used in conjunction with later asymmetric digital subscriber line technology (signals) such as ADSL2+.

It will be readily appreciated by persons skilled in the art that various different embodiments of the basic circuits 200 shown in FIGS. 2(a) and 2(b) can be used. In this regard, FIGS. 2(c) to 2(e) depict alternative embodiments. Persons skilled in the art will also appreciate that the various circuits shown in FIGS. 2(a) to 2(e) are not limited to being implemented using transistors. It is envisaged that other suitable semiconductor devices could be used including, for example, field effect transistors or an appropriate arrangement of discrete diodes. It will be further appreciated by those skilled in the art that the circuits depicted in FIGS. 2(a) to 2(e) are not restricted to being used with the filter 100 and have application to other fields where semiconductor based switching circuits are required.

While the present invention has been described with reference to the aforementioned embodiment, it will be understood by those skilled in the art that alterations, changes and improvements may be made and equivalents may be substituted for the elements thereof and steps thereof without departing from the scope of the present invention. In addition, many modifications may be made to adapt to a particular situation or material to the teachings of the present invention without departing from the central scope thereof. Such alterations, changes, modifications and improvements, though not expressly described above, are nevertheless intended and implied to be within the scope and sprit of the invention. Therefore, it is intended that the invention not be limited to the particular embodiments disclosed as the embodiment for carrying out this invention, but that the invention will include all embodiments falling within the scope of the independent claims.

1. An electronic filter comprising:
a filter section;
an impedance correction section that is electrically coupled to the filter section; and
a circuit altering section that is arranged to alter at least one property of the impedance correction section to effect a shift in a resonant frequency of the impedance correction section from within a pass band of the filter section to within a stop band of the filter section.

2. The electronic filter as claimed in claim 1, wherein the circuit altering section is arranged to alter at least one property of the filter section to effect an increase in a stop band impedance of the filter section.

3. The electronic filter as claimed in claim 2, wherein the property of the filter section comprises a capacitance, and wherein the circuit altering section is arranged to effect the increase in the stop band impedance by reducing the capacitance to a value that is greater than zero farad.

4. The electronic filter as claimed in claim 3, wherein the circuit altering section is arranged to alter the property of the impedance correction section and to alter the property of the filter section based on a subscriber line loop current.

5. The electronic filter as claimed in claim 4, wherein the property of the impedance correction section comprises a damping resistance and a capacitance, and wherein the circuit altering section is arranged to effect the shift in the resonant frequency by decreasing the capacitance, and wherein the circuit altering section is further arranged to increase the damping resistance.

6. The electronic filter as claimed in claim 5, wherein the filter section comprises a plurality of cascaded low pass filters arranged such that the cut-off frequency associated with the pass band and the stop band is around 12 KHz.

7. The electronic filter as claimed in claim 6, wherein the impedance correction section comprises a parallel resonant circuit that is electrically coupled to a first of the cascaded low pass filters and a second of the cascaded low pass filters.

8. The electronic filter as claimed in claim 7, wherein the circuit switching section comprises at least one semiconductor device arranged to alter the property of the impedance correction section and to alter the property of the filter section.

9. An electronic filter comprising:
a filter section; and
a circuit altering section that is arranged to alter at least one property of the filter section to effect an increase in a stop band impedance of the filter section.

10. The electronic filter as claimed in claim 9, wherein the filter further comprises an impedance correction section, and wherein the circuit altering section is arranged to alter at least one property of the impedance correction section to effect a shift in a resonant frequency of the impedance correction section from within a pass band of the filter section to within a stop band of the filter section.

11. The electronic filter as claimed in claim 10, wherein the property of the filter section comprises a capacitance, and wherein the circuit altering section is arranged to effect the increase in the stop band impedance by reducing the capacitance to a value that is greater than zero farad.

12. The electronic filter as claimed in claim 11, wherein the circuit altering section is arranged to alter the property of the impedance correction section and to alter the property of the filter section based on a subscriber line loop current.

13. The electronic filter as claimed in claim 12, wherein the property of the impedance correction section comprises a damping resistance and a capacitance, and wherein the circuit altering section is arranged to effect the shift in the resonant frequency by decreasing the capacitance, and wherein the circuit altering section is arranged to increase the damping resistance.

14. The electronic filter as claimed in claim 13, wherein the filter section comprises a plurality of cascaded low pass filters arranged such that the cut-off frequency associated with the pass band and the stop band is around 12 KHz.

15. The electronic filter as claimed in claim 14, wherein the impedance correction section comprises a parallel resonant circuit that is electrically coupled to a first of the cascaded low pass filters and a second of the cascaded low pass filters.

16. The electronic filter as claimed in claim 15, wherein the circuit switching section comprises at least one semiconductor device arranged to alter the property of the impedance correction section and to alter the property of the filter section.

17. The electronic filter as claimed in claim 1, being an asymmetric digital subscriber line (ADSL) filter.

18. An electronic circuit for use in a switching application, the electronic circuit comprising:
a transistor switch arrangement comprising a base semiconductor region of a first type; and
a semiconductor device having a pn-structure comprising a semiconductor region of the first type that is electrically coupled to the base semiconductor region.

19. The electronic circuit as claimed in claim 18, wherein the semiconductor device comprises a transistor actuator arrangement arranged to switch the transistor switch arrangement between an on-state and an off-state.

20. The electronic circuit as claimed in claim 19, wherein the transistor switch arrangement and the transistor actuator arrangement define a complementary transistor pair in which: a collector of the transistor actuator arrangement is electrically coupled to a base of the transistor switch arrangement; and a base of the transistor actuator arrangement is electrically coupled to an emitter of the transistor switch arrangement, which is also electrically coupled to an emitter of the transistor actuator arrangement.

21. The electronic circuit as claimed in claim 18, being part of an asymmetric digital subscriber line (ADSL) filter.

22-23. (canceled)
